(19) United States
(12) Patent Application Publication
(10) Pub. No.: US 2026/0314468 A1
(43) Pub. Date: Oct. 8, 2026

(54) METHOD FOR MANUFACTURING ELECTRONIC COMPONENT DEVICE AND STENCIL-INTEGRATED MASK FRAME

(71) Applicant: RESONAC CORPORATION, Minato-ku, Tokyo (JP)

(72) Inventors: Motohiro NEGISHI, Minato-ku, Tokyo (JP); Toshiaki SHIRASAKA, Minato-ku, Tokyo (JP)

(21) Appl. No.: 19/480,447

(22) PCT Filed: Dec. 26, 2023
(86) PCT No.: PCT/JP2023/046808

§ 371 Date: Oct. 31, 2025

(51) Int. Cl. H10W 74/01

(52) U.S. Cl. CPC H10W 74/014

(57) ABSTRACT

A method of manufacturing an electronic component device of the present disclosure is such that, on a surface of a mounting body having a circuit board and an electronic component element disposed on one surface of the circuit board, on a side where the electronic component element is disposed, a mask frame having a first opening provided in accordance with a location where the electronic component element is disposed is arranged, a pressing plate is arranged on the side of the mask frame opposite to the side facing the mounting body, and, with a liquid thermosetting resin composition filled in the first opening, a heating and pressing treatment is performed by a pressure-bonding device so as to cure the thermosetting resin composition and thereby seal the electronic component element.

### TECHNICAL FIELD

The present disclosure relates to a method of manufacturing an electronic component device, and to a stencil-integrated mask frame.

### BACKGROUND ART

Conventionally, epoxy resins have been widely used in the fields of molding materials, laminated plates, materials for adhesive agents, and the like. Also, compositions based on epoxy resins have been widely used in the fields of sealing technologies related to the elements of electronic components such as transistors and ICs. This is because epoxy resins provide a well-balanced combination of various properties such as moldability, electrical characteristics, moisture resistance, heat resistance, mechanical properties, and adhesiveness to insert products.

The development of a method called a molded underfill (MUF) has been pursued for a method of sealing a semiconductor chip using an epoxy resin composition. MUF, which is a sealing method in which an underfill and the upper portion of a semiconductor chip are collectively molded, is different from a usual sealing method in which a gap between a semiconductor chip and a substrate is sealed with a liquid underfill material, and the upper portion of the semiconductor chip is then molded.

For example, Japanese Patent Application Laid-Open (JP-A) No. 2021-036581 discloses a method of manufacturing a sealing structure, including: a printing step of printing a liquid curable resin composition on a substrate and covering the substrate with a first coating film of the curable resin composition; and a molding step of covering the first coating film of the curable resin composition with a pressing surface of a die, and compression-molding the first coating film together with substrate, to form a second coating film from the first coating film.

### SUMMARY OF INVENTION

### Technical Problem

As methods for implementing MUF, transfer molding and compression molding are mainly exemplified. However, each of these methods requires large-scale equipment and the arrangement of dedicated molds, resulting in high processing costs, and is therefore associated with the problem of providing low flexibility with respect to small-lot and multi-product production (particularly for evaluations on a laboratory scale).

In JP-A No. 2021-036581, use of a stencil printing method in formation of a sealing material is proposed. However, since it employs a molding machine and a die are used in order to perform compression, preparation of the die is still required even though a step of applying a curable resin composition can be simplified by using the stencil printing method.

One aspect of the present disclosure was made under such conventional circumstances, and is to provide a method of manufacturing an electronic component device capable of easily performing a molded underfill. Another aspect of the present disclosure is to provide a stencil-integrated mask frame applicable to the method of manufacturing an electronic component device.

### Solution to Problem

Specific means for solving the problems described above are as follows.
<1> A method of manufacturing an electronic component device, the method comprising:
arranging, on a surface of a mounting body having a circuit board and an electronic component element disposed on one surface of the circuit board, on a side where the electronic component element is disposed, a mask frame comprising a first opening provided in accordance with a location where the electronic component element is disposed;
arranging a pressing plate on the side of the mask frame opposite to the side facing the mounting body; and
performing heating and pressing treatment by a pressure-bonding device with a liquid thermosetting resin composition is filled in the first opening. with a liquid thermosetting resin composition filled in the first opening portion to cure the thermosetting resin composition and thereby seal the electronic component element.
<2> The method of manufacturing an electronic component device according to <1>, wherein
the thermosetting resin composition is filled into a second opening provided in accordance with a location where the electronic component element is disposed, in a state in which a stencil having the second opening is arranged on the surface of the mounting body on which the electronic component element is disposed, by means of a stencil printing method, and
subsequently, after the stencil is removed, the mask frame and the pressing plate are arranged.
<3> The method of manufacturing an electronic component device according to <2>, wherein the filling of the thermosetting resin composition into the second opening by the stencil printing method is performed under a reduced-pressure environment.
<4> The method of manufacturing an electronic component device according to <1>, wherein
the thermosetting resin composition is filled into the first opening by a dispensing method in a state in which the mask frame is arranged on the surface of the mounting body on which the electronic component element is disposed, and
subsequently, the pressing plate is arranged.
<5> The method of manufacturing an electronic component device according to any one of <1> to <4>, wherein a protrusion that engages with the first opening is provided on the surface of the pressing plate that faces the mask frame.
<6> A stencil-integrated mask frame comprising:
a mask frame comprising a first opening; and
a stencil comprising:
a stencil body that is removable from the mask frame, comes into contact with one surface of the mask frame, and comprises a second opening provided in accordance with a location where the first opening is disposed; and
a wall that protrudes from an edge of the second opening of the stencil body toward a surface in contact with the mask frame and covers at least a part of a wall surface of the first opening.

### Advantageous Effects of Invention

In accordance with one aspect of the present disclosure, a method of manufacturing an electronic component device capable of easily performing a molded underfill can be provided. In accordance with another aspect of the present disclosure, a stencil-integrated mask frame applicable to the method of manufacturing an electronic component device can be provided.

### BRIEF DESCRIPTION OF DRAWINGS

FIG. 1 is a view for explaining a method of manufacturing an electronic component device according to a first embodiment.

FIG. 2 is a view for explaining the method of manufacturing an electronic component device according to the first embodiment.

FIG. 3 is a view for explaining the method of manufacturing an electronic component device according to the first embodiment.

FIG. 4 is a view for explaining the method of manufacturing an electronic component device according to the first embodiment.

FIG. 5 is a view for explaining the method of manufacturing an electronic component device according to the first embodiment.

FIG. 6 is a view for explaining a method of manufacturing an electronic component device according to a second embodiment.

FIG. 7 is a view for explaining the method of manufacturing an electronic component device according to the second embodiment.

FIG. 8 is a view for explaining a method of manufacturing an electronic component device according to a third embodiment.

FIG. 9 is a view for explaining a method of manufacturing an electronic component device according to a fourth embodiment.

FIG. 10 is a view for explaining the method of manufacturing an electronic component device according to the fourth embodiment.

### DESCRIPTION OF EMBODIMENTS

The present disclosure is described in detail below. However, the present disclosure is not limited to the following embodiments. In the following embodiments, the constituent elements (including the element steps and the like) are not indispensable unless otherwise specified. The same applies to numerical values and ranges thereof, and does not limit the present disclosure.

In the present disclosure, the term “step” encompasses a step of which the objective is achieved even in a case in which the step is unable to be definitely distinguished from another step, as well as a step independent from another step.

In the present disclosure, a numerical range expressed by “x to y” includes the values of x and y as the minimum and maximum values, respectively.

In a numerical range expressed in a stepwise manner in the present disclosure, the upper or lower limit value expressed in one numerical range may be replaced by the upper or lower limit value in another numerical range expressed in a stepwise manner.

In the present disclosure, each component may include plural kinds of substances corresponding to the component. In a case in which plural kinds of substances exist corresponding to each component in a composition, the content by percentage or amount of each component means, unless otherwise specified, the total content by percentage or amount of the plural kinds of substances existing in the composition.

In the present disclosure, a particle corresponding to each component may include plural kinds of particles. Unless otherwise specified, the particle size of each component means a value for a mixture of plural kinds of particles existing in a composition in a case in which the plural kinds of particles corresponding to each component exist in the composition.

In the present disclosure, the term “layer” or “film” includes, in the case of observing a region where a layer or film is present, a case in which the layer or the film is formed only on a part of the region, as well as a case in which the layer or the film is formed on the entirety of the region.

In the disclosure, the term “layered” means that layers are layered one on another, in which two or more layers may be bonded or detachable.

In the present disclosure, “(meth)acryl” means at least one of acryl or methacryl, and “(meth)acrylonitrile” means at least one of acrylonitrile or methacrylonitrile.

A method of manufacturing an electronic component device of the present disclosure is such that, on a surface of a mounting body having a circuit board and an electronic component element disposed on one surface of the circuit board, on a side where the electronic component element is disposed, a mask frame having a first opening provided in accordance with a location where the electronic component element is disposed is arranged, a pressing plate is arranged on the side of the mask frame opposite to the side facing the mounting body, and, with a liquid thermosetting resin composition filled in the first opening, a heating and pressing treatment is performed by a pressure-bonding device so as to cure the thermosetting resin composition and thereby seal the electronic component element.

In the method of an electronic component device of the present disclosure, the thermosetting resin composition is cured to seal the electronic component element by performing the heating and pressing treatment by the pressure-bonding device, and a molded underfill can be more easily performed than in the case of sealing an electronic component element by transfer molding, compression molding, or the like.

Supply of the thermosetting resin composition by a stencil printing method or dispensing method described later enables a molded underfill to be more easily performed.

Specific examples of the pressure-bonding device include vacuum laminators, vacuum pressing machines, and hot-pressing machines.

The pressure-bonding device is preferably a reduced-pressure-bonding device, and more preferably a vacuum pressure-bonding device such as a vacuum laminator.

The method of manufacturing an electronic component device of the present disclosure is described below with reference to the drawings. However, the present disclosure is not limited thereto. The size of each of sites in each of the drawings is conceptual, and a relative relationship in each size between the sites is not limited to the size. In the following description, components that are the same as or equivalent to each other are denoted by the same reference characters, and any description overlapped may be omitted.

### First Embodiment

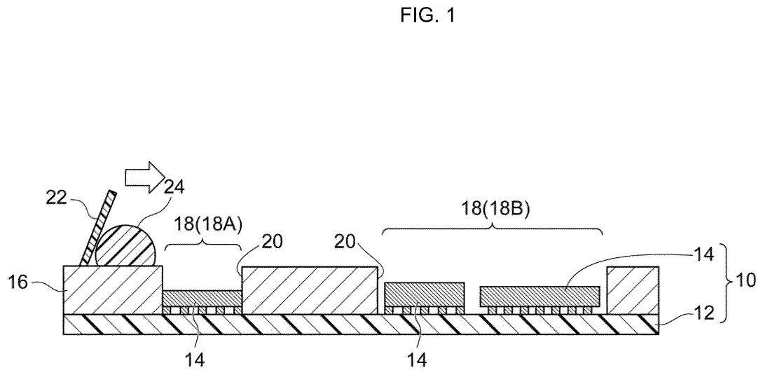

A method of manufacturing an electronic component device according to a first embodiment is described with reference to FIGS. 1 to 5.

In the method of manufacturing an electronic component device according to the first embodiment, a liquid thermosetting resin composition is supplied by a stencil printing method.

As illustrated in FIG. 1, a mounting body 10 includes: a circuit board 12; and electronic component elements 14 arranged on one surface of the circuit board 12.

The circuit board used in the present disclosure is not particularly limited. Examples of the circuit board include a wired tape carrier, an organic substrate such as a copper clad layered plate, a lead frame, a glass substrate, a silicon wafer, a ceramic substrate, and a rewiring layer.

The electronic component element used in the present disclosure is not particularly limited. Examples of the electronic component element include active elements such as semiconductor chips, transistors, diodes, and thyristors, and passive elements such as capacitors, resistors, and coils.

The electronic component elements 14 illustrated in FIG. 1 are bonded to the circuit board 12 via solder balls. Interstices (gaps) are disposed between the electronic component elements 14 and the circuit board 12.

A means to bond the electronic component element to the circuit board is not limited to the solder balls, and examples thereof include wire bonding, Au-Au ultrasonic bonding, copper micro bumps, hybrid bonding, and the like.

On the surface of the mounting body 10 on which the electronic component element 14 is disposed (that is, on a surface, on which the electronic component elements 14 are arranged, of the circuit board 12), a stencil 16 is arranged.

The material of the stencil is not particularly limited. A metal such as iron, aluminum, SUS, or titanium, or a resin such as polyethylene terephthalate (PET), polymethyl methacrylate (PMMA), or a phenol resin is used as the material. The stencil may be a metal mask.

A method of manufacturing a metal mask is not particularly limited, and examples thereof include a laser processing method, an etching method, and an additive method (plating method).

In the stencil 16, second openings 18 are provided in accordance with locations where the electronic component elements 14 are disposed. Each of the second openings 18 may be disposed so that the wall surface 20 of each second opening 18 of the stencil 16 comes into contact with each electronic component element 14 as illustrated in a second opening 18A, or may be disposed so that the wall surface 20 of each second opening 18 of the stencil 16 does not come into contact with each electronic component element 14 as illustrated in a second opening 18B.

Mold release layers may be provided on the surface of the stencil 16 that is in contact with the circuit board 12, on the surface of the stencil 16 opposite to the surface that is in contact with the circuit board 12, and on the wall surface 20. A material included in each of the mold release layers is not particularly limited. Specific examples of the material included in each mold release layer include fluorine rubber, fluorine resin, silicone resin, and polyimide resin.

The thickness of the stencil is not particularly limited, and is selected according to the height of each electronic component element, if appropriate. The thickness of the stencil is preferably from 0.1 mm to 10 mm from the viewpoint of the handleability of the stencil.

The sizes of the second openings are not particularly limited, and the sizes of the second openings may be set so that the electronic component elements are accommodated in the second openings in a planar view of the stencil.

In the case of filling the liquid thermosetting resin composition into a second opening by a stencil printing method, the amount of the liquid thermosetting resin composition filled in the second opening is approximately an amount obtained by subtracting the volume of an electronic component element positioned in the second opening from a volume calculated from the area of the second opening and the thickness of the stencil. Therefore, the size of a second opening and the thickness of the stencil are desirably set so that the amount of liquid thermosetting resin composition filled in the second opening is an amount required for sealing an electronic component element by MUF.

In the case of supplying a liquid thermosetting resin composition by a stencil printing method, the thermosetting resin composition is not filled or is hardly filled between the electronic component element 14 and the circuit board 12 in a case in which the wall surface 20 and the electronic component element 14 come into contact with each other, like in the case of the second opening 18A. In the case of supplying a liquid thermosetting resin composition by a stencil printing method, the thermosetting resin composition is filled between the electronic component element 14 and the circuit board 12 through an interstice in a case in which the interstice exists between the wall surface 20 and the electronic component element 14, like in the case of the second opening 18B. Therefore, it is desirable to take into consideration whether or not a thermosetting resin composition is filled into the interstices between the electronic component elements 14 and the circuit board 12 when determining the sizes of the second openings.

In the stencil printing method, a squeegee 22 is moved in the direction of the arrow in FIG. 1, to fill a thermosetting resin composition 24, supplied onto the stencil 16, into the second openings 18.

The durometer hardness of the squeegee is preferably from 50 to 130, and more preferably from 80 to 100.

The velocity of the squeegee is preferably from 5 mm/sec to 50 mm/sec, and more preferably from 20 mm/sec to 30 mm/sec.

The set printing pressure of the squeegee is preferably from 0.1 MPa to 1.0 MPa, and more preferably from 0.2 MPa to 0.4 MPa.

The supply of the thermosetting resin composition to the mounting body by the stencil printing method may be performed under atmospheric pressure, or may be performed under a reduced-pressure environment. The supply is preferably performed under a reduced-pressure environment, more preferably under an environment at 300 hPa or less, and still more preferably under an environment at 100 hPa or less from the viewpoint of suppressing generation of any void in the thermosetting resin composition supplied onto the mounting body.

The composition and the like of the thermosetting resin composition used in the present disclosure are not limited as long as the thermosetting resin composition is liquid.

In the present disclosure, the phrase that the thermosetting resin composition is ‘liquid’ means that the thermosetting resin composition has a viscosity measured at 25° C. by an E-type viscometer is 1000 Pa·s or less. Specifically, the viscosity is regarded as a value measured after a lapse of 1 minute from start of measurement by using an E-type viscometer (EHD type) (cone angle of 3°, and cone diameter of 28 mm) at a measurement temperature of 25° C., a sample capacity of 0.7 mL, and a rotation number set according to the assumed viscosity of a sample in reference to the following:
(1) a rotation number of 0.5 round/min in a case in which the assumed viscosity is from 100 Pa·s to 1000 Pa·s; and
(2) a rotation number of 5 rounds/min in a case in which the assumed viscosity is less than 100 Pa·s.

The thermosetting resin composition includes a thermosetting resin.

The kind of the thermosetting resin is not particularly limited, and examples thereof include epoxy resins, phenol resins, thiol resins, urea resins, melamine resins, urethane resins, silicone resins, maleimide resins, and unsaturated polyester resins. Such thermosetting resins may be used singly, or in combination of two or more kinds thereof.

Of these, the thermosetting resin is preferably an epoxy resin.

The kind of the epoxy resin is not particularly limited as long as the epoxy resin has two or more epoxy groups in one molecule.

In the following, the thermosetting resin composition in which the epoxy resin is used as the thermosetting resin is described in detail.

The epoxy resin imparts curability and adhesiveness to the thermosetting resin composition, and imparts heat resistance and durability to the cured product of the thermosetting resin composition. The epoxy resin is preferably a liquid epoxy resin. In the present disclosure, a solid epoxy resin can also be used together with a liquid epoxy resin.

The kind of the epoxy resin is not particularly limited. Examples of the epoxy resin include: a naphthalene type epoxy resin; a diglycidyl ether type epoxy resin such as bisphenol A, bisphenol F, bisphenol AD, bisphenol S, or hydrogenated bisphenol A; a resin obtained by epoxidizing a novolac resin of a phenol and an aldehyde, such as an orthocresol novolac type epoxy resin; a glycidyl ester type epoxy resin obtained by reaction between epichlorohydrin and a polybasic acid such as phthalic acid or dimer acid; and a glycidyl amine type epoxy resin obtained by reaction between epichlorohydrin and an amine compound such as diaminodiphenyl methane, isocyanuric acid, or aminophenol.

Examples of the epoxy resin include a bifunctional aliphatic epoxy compound having two epoxy groups in the molecule, such as alkyleneglycol diglycidyl ether, poly(alkyleneglycol)diglycidyl ether, alkenyleneglycol diglycidyl ether.

The epoxy equivalent of the epoxy resin is preferably from 80 g/eq to 400 g/eq, more preferably from 85 g/eq to 350 g/eq, and still more preferably from 90 g/eq to 320 g/eq from the viewpoint of adjusting a viscosity.

The epoxy equivalent of the epoxy resin is measured by dissolving the weighed epoxy resin in a solvent such as methyl ethyl ketone, adding acetic acid and a tetraethylammonium bromide acetate solution, and then performing potentiometric titration with a perchloric acid acetate standard solution. An indicator may be used in the titration.

A commercially available product may be used as the epoxy resin. Specific examples of the commercially available product of the epoxy resin include amine type epoxy resin (product name: jER630) manufactured by Mitsubishi Chemical Corporation, bisphenol F type epoxy resin (product name: YDF-8170C) manufactured by NIPPON STEEL Chemical & Material Co., Ltd., bisphenol A type epoxy resin (product name: YD-128) manufactured by NIPPON STEEL Chemical & Material Co., Ltd., naphthalene type epoxy resin (product name: HP-4032D) manufactured by DIC Corporation, and trade name “EPOGOSEY PT” (general grade) (diglycidyl ether of polytetramethylene glycol, number average molecular weight of from 700 to 800, Yokkaichi Chemical Company Limited). The epoxy resin is not limited to these specific examples. Such epoxy resins may be used singly, or in combination of two or more kinds thereof.

The content of the epoxy resin is not particularly limited, and is, for example, preferably from 5% by mass to 30% by mass, more preferably from 7% by mass to 28% by mass, and still more preferably from 10% by mass to 25% by mass as a percentage with respect to the solid content of the thermosetting resin composition.

The thermosetting resin composition may include a curing agent. The curing agent may be any curing agent of which polymerization reaction with the epoxy resin occurs. Any curing agent which is liquid or solid can be used as the curing agent in a case in which the thermosetting resin composition has fluidity at room temperature (25° C.).

Examples of the curing agent include amine-based curing agents, phenolic curing agents, and acid anhydride-based curing agents.

Examples of the amine-based curing agents include chain aliphatic amine, cyclic aliphatic amine, aliphatic-aromatic amine, and aromatic amine. In view of heat resistance and electrical characteristics, such an amine-based curing agent is preferably an aromatic amine, and more preferably an aromatic amine in which an amino group is directly bound to an aromatic ring, and such one or two aromatic rings are included in one molecule.

Specific examples of the amine-based curing agents include: an aromatic amine curing agent having one aromatic ring, such as m-phenylenediamine, 2,3-diaminotoluene, 3,4-diaminotoluene, 2,4-diaminotoluene, 3,5-diethyl-2,4-diaminotoluene, 3,5-diethyl-2,6-diaminotoluene, or 2,4-diaminoanisole; an aromatic amine curing agent having two aromatic rings, such as 4,4′-diaminodiphenylmethane, 4,4′-diaminodiphenylsulphone, 4,4′-methylenebis(2-ethylaniline), 3,3′-diethyl-4,4′-diaminodiphenylmethane, 3,3′,5,5′-tetramethyl-4,4′-diaminodiphenylmethane, or 3,3′,5,5′-tetraethyl-4,4′-diaminodiphenyl methane; a hydrolysis condensate of an aromatic amine curing agent; an aromatic amine curing agent having a polyether structure, such as polytetramethyleneoxide-di-p-aminobenzoate or polytetramethyleneoxide-di-para-aminobenzoate; a condensate of an aromatic diamine and epichlorohydrin; and a reaction product of an aromatic diamine and styrene.

A commercially available product may be used as such an amine-based curing agent. Specific examples of the commercially available product of the amine-based curing agents include an amine curing agent (product name: KAYAHARD-AA) manufactured by Nippon Kayaku Co., Ltd. and amine curing agents (product name: jERCURE (registered trademark) 113, product name: jERCURE (registered trademark) W, and the like) manufactured by Mitsubishi Chemical Corporation, and the amine-based curing agents are not limited to these specific examples. The amine-based curing agents may be used singly, or in combination of two or more kinds thereof.

Examples of the acid anhydride-based curing agents include various cyclic acid anhydrides such as phthalic anhydride, maleic anhydride, methylhimic anhydride, himic anhydride, succinic anhydride, tetrahydrophtalic anhydride, hexahydrophthalic anhydride, chlorendic anhydride, methyltetrahydrophthalic anhydride, 3-methylhexahydrophthalic anhydride, 4-methylhexahydrophthalic anhydride, an adduct of trialkyltetrahydrophtalic anhydride and maleic acid, benzophenonetetracarboxylic anhydride, trimellitic anhydride, pyromellitic anhydride, hydrogenated methylnadic anhydride, trialkyltetrahydrophtalic anhydride that is obtained from maleic anhydride and a diene compound by Diels-Alder reaction and has a plurality of alkyl groups, and dodecenyl succinic anhydride.

Examples of the phenolic curing agents include: a novolac resin obtained by condensation or cocondensation of at least one selected from the group consisting of phenol compounds (for example, phenol, cresol, xylenol, resorcin, catechol, bisphenol A, and bisphenol F) and naphthol compounds (for example, α-naphthol, β-naphthol, and dihydroxynaphthalene), and an aldehyde compound (for example, formaldehyde, acetaldehyde, propionaldehyde, benzaldehyde, and salicylaldehyde) under an acid catalyst; a phenol/aralkyl resin; a biphenyl/aralkyl resin; and a naphthol/aralkyl resin.

Such curing agents may be used singly, or in combination of two or more kinds thereof.

A ratio between the number of equivalents of the functional group of the curing agent (for example, an amino group in the case of an amine-based curing agent, a phenolic hydroxyl group in the case of a phenolic curing agent, or an acid anhydride group in the case of an acid anhydride-based curing agent) and the number of equivalents of the epoxy resin (the number of equivalents of the curing agent/the number of equivalents of the epoxy resin) is preferably set in a range of from 0.6 to 1.4, more preferably set in a range of from 0.7 to 1.3, and still more preferably set in a range of from 0.8 to 1.2.

The thermosetting resin composition may include an inorganic filler.

A known or common inorganic filler can be used as the inorganic filler, and is not particularly limited.

Examples of the inorganic filler include silicas such as fused silica and crystalline silica, powders such as calcium carbonate, clay, alumina, silicon nitride, silicon carbide, boron nitride, calcium silicate, potassium titanate, aluminum nitride, beryllia, zirconia, zircon, forsterite, steatite, spinel, mullite, and titania, beads obtained by spheroidizing thereof, and glass fibers. Examples of an inorganic filler with a flame-retardant effect include aluminum hydroxide, magnesium hydroxide, zinc borate, and zinc molybdate. Such inorganic fillers may be used singly, or in combination of two or more kinds thereof. Especially, fused silica is preferred from the viewpoint of reducing a linear expansion coefficient, and alumina is preferred from the viewpoint of high thermal conductivity. The shape of such an inorganic filler is preferably spherical from the viewpoint of higher filling of an inorganic filler, and the fluidity and permeation performance of a thermosetting resin composition into fine interstices.

The average particle diameter of such an inorganic filler is preferably from 1 μm to 20 μm, more preferably from 1.5 μm to 15 μm, and still more preferably from 2 μm to 10 μm, particularly in the case of spherical silica. The average particle diameter refers to a particle diameter in which a volume cumulative particle size distribution measured using a laser diffraction method is 50%. In a case in which the average particle diameter of such an inorganic filler is 1 μm or more, high-concentration dispersion of the inorganic filler into the thermosetting resin composition tends to be facilitated. In a case in which the average particle diameter of such an inorganic filler is 20 μm or less, the amount of coarse grain component in the inorganic filler tends to become small, whereby insufficient filling of the thermosetting resin composition into fine interstices or streak-like defects in printing are suppressed, and surface smoothness is improved.

The content of such an inorganic filler is preferably set in a range of from 73% by mass to 93% by mass, and more preferably in a range of from 78% by mass to 91% by mass with respect to the total amount of the thermosetting resin composition. In a case in which the content of the inorganic filler is 73% by mass or more, the effect of reducing the thermal expansion coefficient of the cured product of the thermosetting resin composition tends to be able to be obtained, whereby warpage is reduced. In a case in which the content of the inorganic filler is 93% by mass or less, an increase in the viscosity of the thermosetting resin composition tends to be able to be suppressed, whereby application operation properties become favorable.

The thermosetting resin composition may include a coupling agent, if necessary, in order to strengthen adhesiveness between a resin and an inorganic filler, or between a resin and the configuration member of an electronic component. A known or common coupling agent can be used as the coupling agent, and is not particularly limited.

Examples of the coupling agent include: various silane-based compounds such as a silane compound having at least one selected from the group consisting of a primary amino group, a secondary amino group, and a tertiary amino group, epoxysilane, mercaptosilane, alkylsilane, ureidosilane, and vinylsilane; titanium-based compounds; aluminum chelates; and aluminum/zirconium-based compounds.

In a case in which the thermosetting resin composition includes a coupling agent, the content of the coupling agent is preferably from 0.1% by mass to 2.0% by mass, and more preferably from 0.2% by mass to 1.5% by mass with respect to the total amount of the inorganic filler and the coupling agent. In a case in which the content of the coupling agent is 0.1% by mass or more, the effect of improving the dispersibility of the inorganic filler by the coupling agent tends to be able to be easily obtained. In a case in which the content of the coupling agent is 2.0% by mass or less, voids tend to be inhibited from being generated in the cured product of the thermosetting resin composition.

The thermosetting resin composition may include a curing accelerator. The kind of the curing accelerator is not particularly limited, and a known curing accelerator can be used.

Specific examples thereof include: cycloamidine compounds such as 1,8-diaza-bicyclo[5.4.0]undecene-7, 1,5-diaza-bicyclo[4.3.0]nonene, and 5,6-dibutylamino-1,8-diaza-bicyclo[5.4.0]undecene-7; a compound having intramolecular polarization, obtained by adding, to a cycloamidine compound, a compound having a π-bond, such as maleic anhydride, a quinone compound such as 1,4-benzoquinone, 2,5-toluquinone, 1,4-naphthoquinone, 2,3-dimethylbenzoquinone, 2,6-dimethylbenzoquinone, 2,3-dimethoxy-5-methyl-1,4-benzoquinone, 2,3-dimethoxy-1,4-benzoquinone, or phenyl-1,4-benzoquinone, diazophenylmethane, or phenol resin; a tertiary amine compound such as benzyldimethylamine, triethanolamine, dimethylaminoethanol, or tris(dimethylaminomethyl)phenol; a derivative of a tertiary amine compound; an imidazole compound such as 2-methylimidazole, 2-phenylimidazole, or 2-phenyl-4-methylimidazole; a derivative of an imidazole compound; an organic phosphine compound such as tributylphosphine, methyldiphenylphosphine, triphenylphosphine, tris(4-methylphenyl)phosphine, diphenylphosphine, or phenylphosphine; a phosphorus compound having intramolecular polarization, obtained by adding, to an organic phosphine compound, a compound having a π-bond, such as maleic anhydride, the quinone compounds described above, diazophenylmethane, or phenol resin; a tetraphenylborate such as tetraphenylphosphonium tetraphenylborate, triphenylphosphine tetraphenylborate, 2-ethyl-4-methylimidazole tetraphenylborate, N-methylmorpholine tetraphenylborate; a derivative of a tetraphenylborate; and an adduct of a phosphine compound and a tetraphenylborate, such as triphenylphosphonium-triphenylborane or N-methylmorpholinetetraphenylphosphonium-tetraphenylborate. Such curing accelerators may be used singly, or in combination of two or more kinds thereof.

The content of the curing accelerator is preferably from 0.1% by mass to 8% by mass with respect to the total amount of the epoxy resin and the curing agent.

The thermosetting resin composition may include an ion trapping agent.

The ion trapping agent that can be used in the present disclosure is not particularly limited as long as the ion trapping agent is an ion trapping agent that is commonly used in a sealing material used for manufacturing an electronic component device. Examples of the ion trapping agent include a compound represented by the following Formula (VI-1) or (VI 2).

Mg₁₋ₐAlₐ(OH)₂(CO₃)_{a/2}·uH₂O (VI-1)

(In Formula (VI-1), a is 0<a≤0.5, and u is a positive number.)

BiO_{b}(OH)_{c}(NO₃)_{d} (VI-2)

(In Formula (VI-2), b is 0.9≤b≤1.1, c is 0.6≤c≤0.8, and d is 0.2≤d≤0.4.)

The ion trapping agent can be obtained as a commercially available product. For example, “DHT-4A” (trade name, Kyowa Chemical Industry Co., Ltd. ,) can be obtained as a commercially available product for the compound represented by Formula (VI-1). For example, “IXE 500” (trade name, TOAGOSEI CO., LTD.) can be obtained as a commercially available product for the compound represented by Formula (VI-2).

Examples of an ion trapping agent except the above include a hydrous oxide of an element selected from magnesium, aluminum, titanium, zirconium, antimony, or the like.

Such ion trapping agents may be used singly, or in combination of two or more kinds thereof.

In a case in which the thermosetting resin composition includes an ion trapping agent, the content of the ion trapping agent is preferably 1 part by mass or more with respect to 100 parts by mass of the epoxy resin from the viewpoint of achieving sufficient moisture proof reliability. The content of the ion trapping agent is preferably 15 parts by mass or less, more preferably from 1 part by mass to 10 parts by mass, and still more preferably from 2 parts by mass to 5 parts by mass with respect to 100 parts by mass of the epoxy resin from the viewpoint of exerting the sufficiently effects of the other components.

The average particle diameter of the ion trapping agent is preferably from 0.1 μm to 3.0 μm, and the maximum particle diameter of the ion trapping agent is preferably 10 μm or less. The average particle diameter of the ion trapping agent can be measured in a manner similar to the manner in the case of the inorganic filler.

The thermosetting resin composition may include an antioxidant. A conventionally known antioxidant can be used as the antioxidant.

Such antioxidants may be used singly, or in combination of two or more kinds thereof. Specific examples of the antioxidant include a compound including a phenolic hydroxyl group and at least any one of a phosphorus atom, a sulfur atom, or amine in the same molecule. Such compounds may be repeatedly mentioned.

The content of the antioxidant is preferably from 0.1% by mass to 10% by mass, and more preferably from 0.5% by mass to 5% by mass with respect to the total epoxy resin.

The thermosetting resin composition can be blended with an organic solvent in order to decrease a viscosity, if necessary. Particularly in the case of using an epoxy resin and a curing agent which are solid, an organic solvent is preferably blended in order to obtain a thermosetting resin composition.

The organic solvent is not particularly limited. Examples of the organic solvent include: an alcohol-based solvent such as methyl alcohol, ethyl alcohol, propyl alcohol, or butyl alcohol; a ketone-based solvent such as acetone or methyl ethyl ketone; a glycol ether-based solvent such as ethylene glycol ethyl ether, ethylene glycol methyl ether, ethylene glycol butyl ether, propylene glycol methyl ether, dipropylene glycol methyl ether, propylene glycol ethyl ether, or propylene glycol methyl ether acetate; a lactone-based solvent such as γ-butyrolactone, δ-valerolactone, or ε-caprolactone; an amide-based solvent such as dimethylacetamide or dimethylformamide; and an aromatic solvent such as toluene or xylene. Such organic solvents may be used singly, or in combination of two or more kinds thereof. Of these, an organic solvent having a boiling point of 170° C. or more is preferred from the viewpoint of avoiding formation of bubbles, caused by rapid volatilization in the case of curing the thermosetting resin composition.

The content of volatile matter including the organic solvent and the like is not particularly limited as long as any bubble is not formed in the case of curing the thermosetting resin composition. The content is preferably 5% by mass or less, more preferably 1% by mass or less, and still more preferably 0.1% by mass or less with respect to the total of the thermosetting resin composition.

In the present disclosure, the volatile matter of the thermosetting resin composition is calculated based on a weight difference before and after heating of the thermosetting resin composition under conditions of 180° C. and 30 minutes.

The thermosetting resin composition may include a mold release agent. The kind of the mold release agent is not particularly limited, and a known mold release agent can be used. Specific examples thereof include a higher fatty acid, carnauba wax, and polyethylene-based wax. Such mold release agents may be used singly, or in combination of two or more kinds thereof.

In a case in which the thermosetting resin composition includes a mold release agent, the content of the mold release agent is preferably 10% by mass or less with respect to the total amount of the epoxy resin and the curing agent, and preferably 0.5% by mass or more from the viewpoint of exerting the effect thereof.

The thermosetting resin composition may include a coloring agent (for example, carbon black). Such coloring agents may be used singly, or in combination of two or more kinds thereof.

In the case of using conductive particles such as carbon black as the coloring agent, the content of the conductive particles having a particle diameter of 10 μm or more is preferably 1% by mass or less.

In a case in which the thermosetting resin composition includes conductive particles, the content of the conductive particles is preferably 3% by mass or less, and more preferably from 0.01% by mass to 1% by mass with respect to the total amount of the epoxy resin and the curing agent.

The thermosetting resin composition may include rubber particles from the viewpoint of decreasing the thermal expansion of the cured product. Such rubber particles may be used singly, or in combination of two or more kinds thereof.

Preferred examples of the rubber particles include the rubber particles of styrene-butadiene rubber (SBR), nitrile-butadiene rubber (NBR), butadiene rubber (BR), urethane rubber (UR), acrylic rubber (AR), or the like. Especially, rubber particles including acrylic rubber are preferred, and core-shell-type acrylic rubber particles are more preferred from the viewpoint of heat resistance and moisture resistance.

Other preferred examples of the rubber particles include silicone rubber particles.

Examples of the silicone rubber particles include: silicone rubber particles in which a straight-chain polyorganosiloxane such as polydimethylsiloxane, polymethylphenylsiloxane, or polydiphenylsiloxane is crosslinked; particles obtained by coating the surfaces of the silicone rubber particles with silicone resin; and core-shell polymerized particles including the core of a solid silicone particle and the shell of an organic polymer such as acryl resin, obtained by emulsion polymerization or the like. The shapes of these silicone rubber particles may be amorphous or spherical. Spherical silicone rubber particles are preferably used in order to reduce the viscosity of the thermosetting resin composition to a low level.

For the silicone rubber particles, a commercially available product can be obtained from Dow Corning Toray Company, Shin-Etsu Chemical Co., Ltd., or the like.

In a case in which the thermosetting resin composition includes rubber particles, the average particle diameter of the rubber particles is preferably fine in order to uniformly modify the thermosetting resin composition. The average particle diameter of the rubber particles is preferably in a range of from 0.05 μm to 10 μm, and still more preferably in a range of from 0.1 μm to 5 μm. In a case in which the average particle diameter of the rubber particles is 0.05 μm or more, the dispersibility thereof in the thermosetting resin composition tends to be further improved. In a case in which the volume-average particle diameter of the rubber particles is 10 μm or less, the effect of improving a reduction in stress tends to be further improved, the permeation performance and fluidity of the thermosetting resin composition into fine interstices are improved, and voids and non filling tend to be inhibited.

The average particle diameter of the rubber particles is measured using a method similar to the method in the case of the inorganic filler.

The thermosetting resin composition can be obtained by, for example, collectively or separately stirring, melting, mixing, or dispersing each component included in the thermosetting resin composition, while performing heat treatment, if necessary. A device for, for example, mixing, stirring, or dispersing such components is not particularly limited, and examples thereof include a grinding machine including a stirring device, a heating device, or the like, a three-roll mill, a ball mill, a planetary mixer, or a bead mill. The thermosetting resin composition can be obtained by mixing and kneading the above-described components by using such devices, and by defoaming the resultant, if necessary.

A mixture in which an inorganic filler has been mixed with an epoxy resin in advance may be used for the purpose of improving the dispersibility of the inorganic filler. In this case, the content of the inorganic filler in the mixture is preferably from 20% by mass to 70% by mass.

The viscosity of the thermosetting resin composition is not particularly limited.

Especially, from the viewpoint of high fluidity, the viscosity is preferably from 0.1 Pa·s to 50.0 Pa·s, more preferably from 1.0 Pa·s to 50.0 Pa·s, and still more preferably from 10.0 Pa·s to 50.0 Pa·s at 25° C.

The viscosity of the thermosetting resin composition at 110° C. is preferably 0.20 Pa·s or less, and more preferably 0.15 Pa·s or less as an index for ease in filling in the case of filling the thermosetting resin composition into a narrow gap of from several tens of micrometers to several hundreds of micrometers from around 100° C. to 120 °C. The viscosity of the thermosetting resin composition at 110° C. is measured by a Rheometer AR 2000 (manufactured by TA Instruments, aluminum cone of 40 mm, shear rate of 32.5/sec).

A thixotropy index which is a ratio between the viscosities of the thermosetting resin composition at a rotation number of 2.5 rounds/min and a rotation number of 10 rounds/min, measured at 25° C. by using an E-type viscometer, respectively [(viscosity at 2.5 rounds/min)/(viscosity at 10 rounds/min)] is preferably from 0.3 to 1.5, and more preferably from 0.5 to 1.2. A filling property tends to be further improved in a case in which the thixotropy index is in the range described above. The viscosity and thixotropy index of the thermosetting resin composition can be allowed to be in a desired range by selecting the composition of the epoxy resin, the contents of the inorganic filler, or the like, if appropriate.

The thermosetting resin composition 24 is filled in the second openings 18 by a stencil printing method, and the stencil 16 is then removed from the mounting body 10. In such a manner, a thermosetting resin composition layer 26 is formed on the mounting body 10 (surface, on which the electronic component elements 14 are arranged, of the circuit board 12).

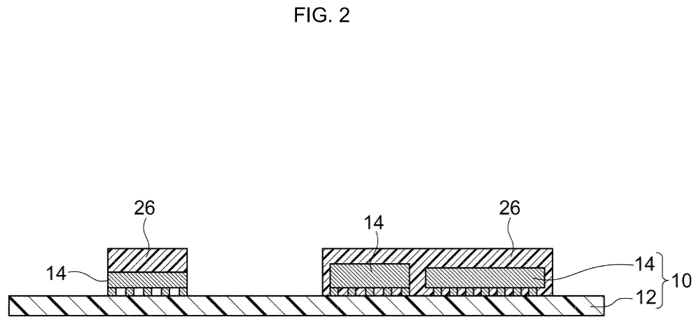

With regard to the electronic component element 14 arranged in the second opening 18A, the thermosetting resin composition 24 is applied to the top surface of the electronic component element 14, to form the thermosetting resin layer 26, as illustrated in FIG. 2. With regard to the electronic component element 14 arranged in the second opening 18B, the thermosetting resin composition 24 is applied to the upper surface and side of the electronic component element 14, and between the electronic component element 14 and the circuit board 12, to form the thermosetting resin layer 26.

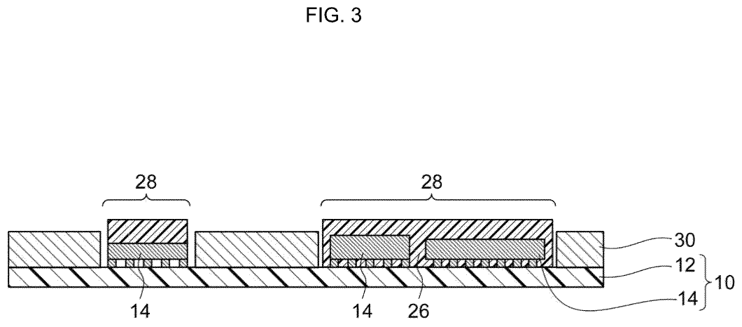

Then, a mask frame 30 including first openings 28 provided in accordance with locations where the electronic component elements 14 are disposed is arranged on the surface of a mounting body 10 on the side where the electronic component elements 14 are disposed (that is, on a surface, on which the electronic component elements 14 are arranged, of the circuit board 12), as illustrated in FIG. 3. In the present embodiment, the thickness of the mask frame 30 is set to be smaller than the thickness of the thermosetting resin composition layer 26.

The material of the mask frame is not particularly limited, and examples thereof include metals such as iron, aluminum, SUS, and titanium. The mask frame can be manufactured by a method similar to the method in the case of the metal mask.

Mold release layers may be provided on the surface of the mask frame 30 that is in contact with the circuit board 12, on the surface of the mask frame 30 opposite to the surface that is in contact with the circuit board 12, and on the wall surface of the first opening 28 of the mask frame 30. A material included in each of the mold release layers is not particularly limited. Specific examples of the material included in each mold release layer include fluorine rubber, fluorine resin, silicone resin, and polyimide resin.

The sizes of the first openings 28 are not particularly limited, and the sizes of the first openings 28 may be set so that the electronic component elements are accommodated in the first openings in a planar view of the mask frame 30.

When the mask frame 30 is arranged on the mounting body 10, in order to prevent the thermosetting resin composition 24 from existing between the mask frame 30 and the circuit board 12, which would contaminate the surface of the circuit board 12 with the thermosetting resin composition 24, the first openings 28 are preferably provided such that the wall surfaces of the first openings 28 of the mask frame 30 does not come into contact with the electronic component elements 14.

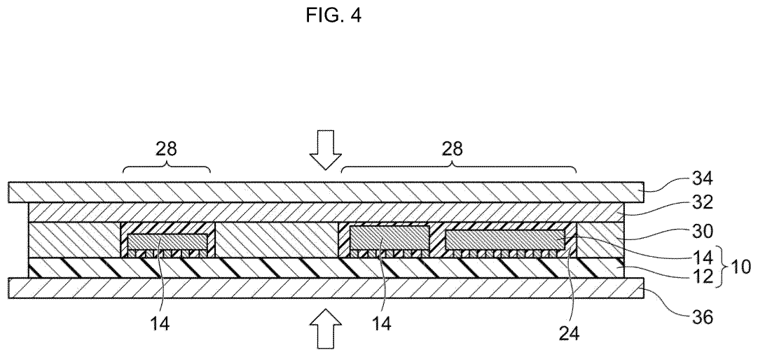

Then, a pressing plate 32, of which the surfaces are smooth, is arranged on a side of the mask frame 30 opposite to the side facing the mounting body 10, as illustrated in FIG. 4.

The size of the pressing plate 32 is not particularly limited, and may be, for example, a size capable of covering the spots on which the first openings 28 are disposed in the mask frame 30.

A mold release sheet may be arranged between the mask frame 30 and the pressing plate 32 in order to allow the mask frame 30 and the pressing plate 32 to be easily separated after heating and pressing treatment by a pressure-bonding device.

The mold release sheet may be a mold release sheet including: a base material including polyethylene terephthalate resin, polyethylene naphthalate resin, or polybutylene terephthalate resin, or a copolymer or modified resin thereof, and a mold release layer that is disposed on one surface of the base material, and includes resin particles, a binder, and, if necessary, another component.

Examples of the resin particles include at least one selected from the group consisting of (meth)acryl resin, polyolefin resin, polystyrene resin, poly(meth)acrylonitrile resin, and silicone resin. Examples of the binder include (meth)acryl resin or silicone resin.

The mold release sheet may be arranged so that a surface having the mold release layer comes into contact with the mask frame 30.

The thermosetting resin composition 24 is cured to seal the electronic component elements 14 with the cured product of the thermosetting resin composition 24 by performing heating and pressing treatment while applying pressure in the direction of the arrows in FIG. 4 by using a pressure-bonding device including a pair of a plate 34 and a plate 36 in a state in which the pressing plate 32 is arranged on the side of the mask frame 30 opposite to the side facing the mounting body 10 and the thermosetting resin composition 24 which is liquid is filled into the first openings 28.

A condition under which the thermosetting resin composition is cured using the pressure-bonding device is not particularly limited, and can be set based on a component included in the thermosetting resin composition, if appropriate. For example, heating from 80° C. to 165° C. for from 1 minute to 150 minutes is preferred as such conditions under which the thermosetting resin composition is cured. A condition of from 0.5 MPa to 1.0 MPa is preferred as a pressing condition.

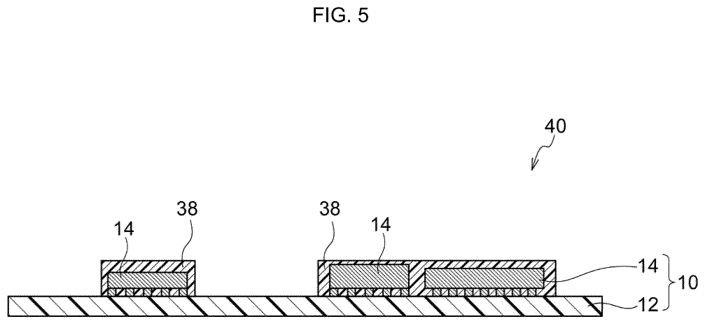

After the heating and pressing treatment, the pressing plate 32 and the mask frame 30 are removed, to obtain an electronic component device 40 including the electronic component elements 14 sealed with cured products 38 as illustrated in FIG. 5.

Surfaces of the cured products 38 in the electronic component device 40 may be subjected to polishing treatment by a grinder, a buff, or the like.

Postcure of the cured products 38 may be performed. The condition of the postcure is not particularly limited, and can be set based on a component included in the thermosetting resin composition, if appropriate. For example, heating from 100° C. to 180° C. for from 30 minutes to 120 minutes is possible as such conditions of the postcure.

### Second Embodiment

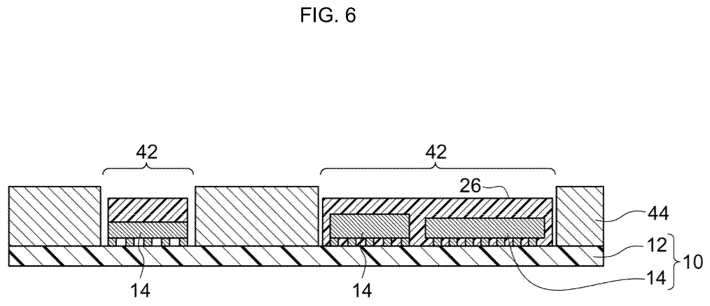

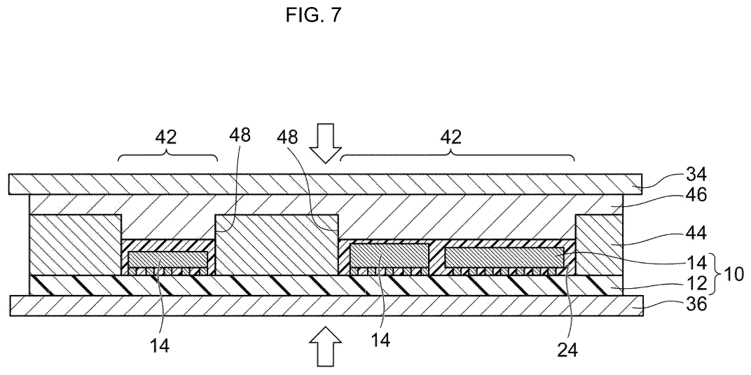

A method of manufacturing an electronic component device according to a second embodiment is described with reference to FIGS. 6 to 7.

Unlike the case of the first embodiment, the thickness of a mask frame is set to be larger than the thickness of a thermosetting resin composition layer in the method of manufacturing an electronic component device according to the second embodiment. A protrusion that engages with the first opening of the mask frame is disposed on a surface, facing the mask frame, of a pressing plate.

In the method of manufacturing an electronic component device according to the second embodiment, a thermosetting resin composition is supplied onto a mounting body by a stencil printing method in a manner similar to the manner in the first embodiment, as illustrated in FIGS. 1 to 2.

Then, a mask frame 44 including first openings 42 provided in accordance with locations where the electronic component elements 14 are disposed is arranged on the surface of a mounting body 10 on the side where the electronic component elements 14 are disposed (that is, on a surface, on which the electronic component elements 14 are arranged, of a circuit board 12), as illustrated in FIG. 6. In the present embodiment, the thickness of the mask frame 44 is set to be larger than the thickness of a thermosetting resin composition layer 26.

Then, a pressing plate 46 is arranged on a side of the mask frame 44 opposite to the side facing the mounting body 10, as illustrated in FIG. 7. Protrusions 48 that engages with the first openings 42 are provided on a surface, facing the mask frame 44, of the pressing plate 46.

Use of the pressing plate 46, on which the protrusions 48 are provided, enables the thickness of a thermosetting resin composition 24 to be adjusted according to each electronic component element 14. Therefore, electronic component elements having different heights can be collectively sealed.

A mold release sheet may be arranged between the mask frame 44 and the pressing plate 46 in order to allow the mask frame 44 and the pressing plate 46 to be easily separated after heating and pressing treatment by a pressure-bonding device. The details of the mold release sheet are as described above.

By then performing heating and pressing treatment by using the pressure-bonding device in a manner similar to the manner in the first embodiment, the thermosetting resin composition 24 is cured to seal the electronic component elements 14 with a cured product of the thermosetting resin composition 24, to manufacture an electronic component device.

### Third Embodiment

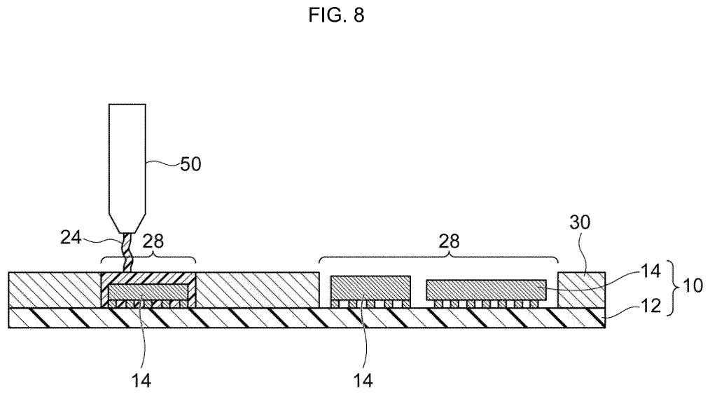

A method of manufacturing an electronic component device according to a third embodiment is described with reference to FIG. 8.

In the method of manufacturing an electronic component device according to the third embodiment, a thermosetting resin composition is supplied onto a mounting body by a dispensing method instead of the stencil printing method.

In the method of manufacturing an electronic component device according to the third embodiment, a mask frame 30 including first openings 28 provided in accordance with locations where the electronic component elements 14 are disposed is arranged on the surface of the mounting body 10 where the electronic component elements 14 are disposed, as illustrated in FIG. 8.

Then, a thermosetting resin composition 24 is filled into the first openings 28 by using a dispenser 50. The amount of the thermosetting resin composition 24 filled into the first openings 28 is set so that the amount is an amount required for sealing the electronic component elements 14 by MUF.

Examples of the dispenser include an air syringe system, a tubing system, a plunger system, a positive load system, a screw system (mohno pump), and a non-contact (jet) system.

In the method of manufacturing an electronic component device according to the third embodiment, the thermosetting resin composition is directly filled into the first openings by using the dispenser. Therefore, a step of preparing a stencil can be omitted unlike the case of the first embodiment or the second embodiment using the stencil printing method.

In the method of manufacturing an electronic component device according to the third embodiment, any stencil is not used. Therefore, the contamination of the surface of the circuit board with the thermosetting resin composition, which may occur during removal of the stencil after the supply of the thermosetting resin composition by the stencil printing method and the subsequent arrangement of the mask frame, is avoided.

Subsequently, by performing heating and pressing treatment using the pressure-bonding device as in the first embodiment, the thermosetting resin composition 24 is cured so that the electronic component elements 14 are sealed with a cured product of the thermosetting resin composition 24, thereby manufacturing an electronic component device.

### Fourth Embodiment

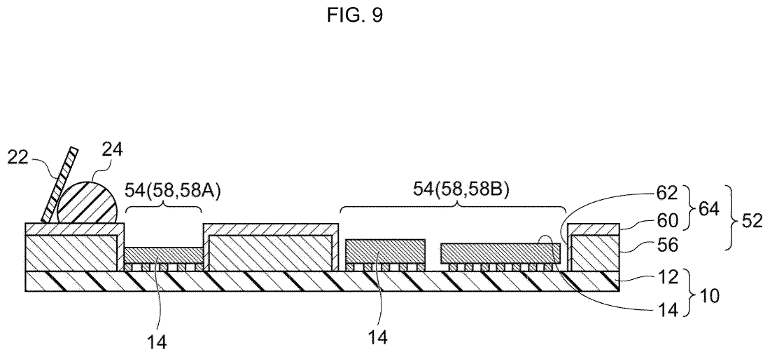

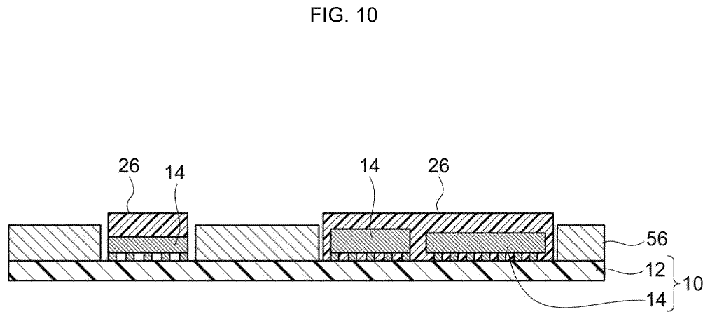

A method of manufacturing an electronic component device according to a fourth embodiment is described with reference to FIGS. 9 to 10.

In the fourth embodiment, a thermosetting resin composition is supplied onto a mounting body by a stencil printing method using the stencil-integrated mask frame of the present disclosure.

A stencil-integrated mask frame 52 used in the fourth embodiment includes: a mask frame 56 including first openings 54; and a stencil 64 including: a stencil body 60 that is removable from the mask frame 56, comes into contact with one surface of the mask frame 56, and includes second openings 58 provided in accordance with locations where the first openings 54 are disposed; and walls 62 that protrude from the edges of the second openings 58 of the stencil body 60 toward a surface coming into contact with the mask frame 56, and covers at least a part of the wall surfaces of the first openings 54, as illustrated in FIG. 9.

In the present embodiment, the height of each of the walls 62 is set to be equal to the thickness of the mask frame 56, and the front ends of the walls 62 come into contact with a circuit board 12; however, the conditions are not limited thereto, and the front ends of the walls 62 need not come into contact with the circuit board 12.

The materials of the mask frame 30 and the stencil 16 can be applied to the materials of the mask frame 56 and the stencil 64, respectively.

In the method of manufacturing an electronic component device according to the fourth embodiment, the stencil-integrated mask frame 52 is arranged on a surface of a mounting body 10 where the electronic component elements 14 are arranged. As illustrated in FIG. 9, the first openings 54 and the second openings 58 in the stencil-integrated mask frame 52 are provided in accordance with locations where the electronic component elements 14 are disposed. Each of the walls 62 may be disposed so as to come into contact with each electronic component element 14 as illustrated in a second opening 58A. Each of the walls 62 may be disposed so as not to come into contact with each electronic component element 14 as illustrated in a second opening 58B.

In the stencil printing method, a thermosetting resin composition 24 supplied onto the stencil body 60 is filled in the second openings 58 by using a squeegee 22. The details of the stencil printing method are similar to those in the first embodiment.

The thermosetting resin composition 24 is filled into the second openings 58 by the stencil printing method, and the stencil 64 is then removed from the mounting body 10, as illustrated in FIG. 10. In such a manner, a thermosetting resin composition layer 26 is formed on the mounting body 10 (that is, the surface, on which the electronic component elements 14 are arranged, of the circuit board 12). At this time, since the mask frame 56 remains on the circuit board 12 without being removed, the thermosetting resin composition 24 does not exist between the mask frame 56 and the circuit board 12. Therefore, contamination of the surface of the circuit board 12 with the thermosetting resin composition 24 is suppressed.

Subsequently, by performing heating and pressing treatment using the pressure-bonding device as in the first embodiment, the thermosetting resin composition 24 is cured so that the electronic component elements 14 are sealed with a cured product of the thermosetting resin composition 24, thereby manufacturing an electronic component device.

### Additional Embodiment

The method of manufacturing an electronic component device of the present disclosure is also preferably applicable to repairing a spot in which a defect, such as a crack, is generated in a cured product of a thermosetting resin composition.

For example, a spot in which a defect is generated can be repaired by allowing a thermosetting resin composition to adhere to the spot in which the defect is generated in a state in which a mask frame is arranged, and curing the thermosetting resin composition, allowed to adhere, by a pressure-bonding device.

The method of manufacturing an electronic component device of the present disclosure can also be applied to the sealing of a mounting body having a curved surface. Unlike a conventional sealing method using a die, the method of manufacturing an electronic component device of the present disclosure employs the mask frame. Therefore, an electronic component element on the mounting body having a curved surface can be easily sealed by a pressure-bonding device by using the mask frame exhibiting flexibility.

The present invention is not limited to the four embodiments described above, and various modifications may be made by known findings as long as the gist of the present disclosure is not changed.

All documents, patent applications, and technical standards described in this specification are herein incorporated by reference to the same extent as if each individual document, patent application, and technical standard were specifically and individually indicated to be incorporated by reference.

1. A method of manufacturing an electronic component device, the method comprising:
arranging, on a surface of a mounting body having a circuit board and an electronic component element disposed on one surface of the circuit board, on a side where the electronic component element is disposed, a mask frame comprising a first opening provided in accordance with a location where the electronic component element is disposed;
arranging a pressing plate on the side of the mask frame opposite to the side facing the mounting body; and
performing heating and pressing treatment by a pressure-bonding device with a liquid thermosetting resin composition is filled in the first opening. with a liquid thermosetting resin composition filled in the first opening portion to cure the thermosetting resin composition and thereby seal the electronic component element.

2. The method of manufacturing an electronic component device according to claim 1, wherein
the thermosetting resin composition is filled into a second opening provided in accordance with a location where the electronic component element is disposed, in a state in which a stencil having the second opening is arranged on the surface of the mounting body on which the electronic component element is disposed, by means of a stencil printing method, and
subsequently, after the stencil is removed, the mask frame and the pressing plate are arranged.

3. The method of manufacturing an electronic component device according to claim 2, wherein the filling of the thermosetting resin composition into the second opening by the stencil printing method is performed under a reduced-pressure environment.

4. The method of manufacturing an electronic component device according to claim 1, wherein
the thermosetting resin composition is filled into the first opening by a dispensing method in a state in which the mask frame is arranged on the surface of the mounting body on which the electronic component element is disposed, and
subsequently, the pressing plate is arranged.

5. The method of manufacturing an electronic component device according to claim 1, wherein a protrusion that engages with the first opening is provided on the surface of the pressing plate that faces the mask frame.

6. A stencil-integrated mask frame comprising:
a mask frame comprising a first opening; and
a stencil comprising:
a stencil body that is removable from the mask frame, comes into contact with one surface of the mask frame, and comprises a second opening provided in accordance with a location where the first opening is disposed; and
a wall that protrudes from an edge of the second opening of the stencil body toward a surface in contact with the mask frame and covers at least a part of a wall surface of the first opening.
